(19) United States
(12) Patent Application Publication
(10) Pub. No.: US 2003/0113960 A1
(43) Pub. Date: Jun. 19, 2003

(54) Method of fabricating a MOS transistor with low gate depletion

(76) Inventor: Kent Kuohua Chang, Taipei City (TW)

Correspondence Address: NAIPO (NORTH AMERICA INTERNATIONAL PATENT OFFICE), P.O. BOX 506, MERRIFIELD, VA, 22116, US

(21) Appl. No.: 09/683,324

(22) Filed: Dec. 19, 2001

(51) Int. Cl. H01L 21/00; H01L 21/84; H01L 21/8238; H01L 21/336

(52) U.S. Cl. 438/154; 438/303; 438/230

(57) ABSTRACT

A semiconductor wafer is provided having both a memory array area and a periphery circuit region defined on the surface of the semiconductor wafer. A gate composed of a silicon oxide layer and a silicon germanium layer is formed on the surface of the periphery circuit region, and a spacer, a source and a drain of the MOS transistor are formed around the gate. Finally, a nickel (Ni) layer is formed on the surface of the source and the drain, and a rapid thermal annealing process (RTA process) with a temperature ranging between 400° C. and 500° C. is performed for forming a silicon nickel layer on the surface of the source and the drain. Additionally, a shallow junction for the source and the drain is formed.

### BACKGROUND OF INVENTION

1. Field of the Invention

The present invention relates to a method of fabricating a shallow junction on a semiconductor wafer. In particular, the present invention discloses a method of fabricating a metal-oxide semiconductor (MOS) transistor with a shallow junction in nitride read only memory (NROM).

2. Description of the Prior Art

Nitride read only memory (NROM), comprising a plurality of memory cells, is used to store data. Each memory cell comprises a control gate, and a gate dielectric layer that has an oxide-nitride-oxide (ONO) structure. Since the silicon nitride layer of the ONO gate dielectric layer is highly compact, hot electrons tunneling through the MOS transistor become trapped in the silicon nitride layer, which is used as a floating gate for storing data.

Please refer to FIG. 1 to FIG. 6. FIG. 1 to FIG. 6 are cross-sectional diagrams of a method of forming an NROM according to the prior art. As shown in FIG. 1, the prior art method first provides a semiconductor wafer 10 with both a memory array area 11 and a periphery circuit region 13 defined on the surface of a silicon substrate 12 of the semiconductor wafer 10.

The first step of the prior method is to perform a conventional oxide-nitrideoxide (ONO) process to form an ONO dielectric layer composed of a bottom oxide layer 14, a silicon nitride layer 16, and a top oxide layer 18, all of which are formed on the surface of the silicon substrate 12. The bottom oxide layer 14 is a silicon oxide layer grown over the silicon substrate 12, typically to a thickness of between 50 Å and 150 Å, in a thermal oxidation operation. A typical oxidation temperature is between 750° C. and 1000° C. The thickness of the silicon nitride layer 16 is between 20 Å and 150 Å. The top oxide layer 18 is an oxidative silicon nitride layer or a deposited silicon oxide layer, with a thickness that is between 50 Å and 150 Å.

The next step, as shown in FIG. 2, involves forming a patterned photoresist layer 20 on the memory array area 11 for defining positions of bit lines 22. The photoresisit layer 20 is used as a mask to perform an anisotropic dry etching process, which removes both the top oxide layer 18 and the silicon nitride layer 16 that are not covered by the photoresist layer 20, exposing the surface of the bottom oxide layer 14 or the silicon substrate 12. An ion implantation process follows, which is performed to form a plurality of doped areas in the silicon substrate 12 that function as bit lines 22. The dosage of the ion implantation process is 2˜4×10¹⁵/cm², and the implantation energy is approximately 50 KeV.

As shown in FIG. 3, the photoresist layer 20 is then removed and a thermal oxidation method, with a temperature of 800° C.˜950° C., is used to form an oxide layer 24 with a thickness of 500 Å on the surface of the bit lines 22 so as to separate each ONO dielectric layer. In addition, the thermal oxidation method also activates dopants in the doped areas.

The formation of MOS transistors in the periphery circuit region 13 first utilizes a photo mask that has patterns for both the memory array area 11 and periphery circuit region 13, as shown in FIG. 4, to sequentially perform an etching and an oxidation process to the periphery circuit region 13 so as to remove the ONO dielectric layer previously formed on the surface of the silicon substrate 12. A gate oxide layer 26 is then formed. That is, the mask is first used to form a patterned photoresist layer (not shown) in the memory array area 11. The ONO dielectric layer in the periphery circuit region 13 is then used as a sacrificial layer when performing an ion implantation process to adjust the threshold voltage of MOS transistors in the periphery circuit region 13. Thereafter, a dry etching process is performed to sequentially remove the top oxide layer 18 and the silicon nitride layer 16, and a wet etching process is performed to remove the bottom oxide layer 14. Finally, the photoresist layer is removed and a thermal oxidation process is performed to form a silicon oxide layer 26 with a thickness of 100 Å-150 Å on the surface of the silicon substrate 12, which functions as a gate oxide layer 26 of the MOS transistor in the periphery circuit region 13. Due to the presence of the silicon nitride layer 16 in the memory array area 11, the thermal oxidation process does not significantly affect the thickness of the top oxide layer 18.

Following the gate oxide layer 26 growth step, a polysilicon layer is deposited over the silicon substrate 12, which is used to create word lines 28 for the memory array area 11, as shown in FIG. 5, and is further used to create gate conductive layers 30 for the MOS transistors in the periphery circuit region 13. Thereafter, a standard process is performed to complete the formation of the MOS transistors in the periphery circuit region 13. An ion implantation process is first performed in the periphery circuit region 13 to form a lightly doped drain (LDD) 32 for each MOS transistor, and a spacer 33 is formed along the side wall of each MOS transistor. Then, another ion implantation process is performed to form a source 35 and a drain 37 in the silicon substrate 12 on either side of each MOS transistor. Finally, a silicide layer 38 is on the surface of the source 35 and the drain 37, as shown in FIG. 6.

As the dimensions of electronic components become smaller, improvements to ion implantation processes focus on the fabrication of shallow junctions, such as lightly doped drains (LDD), sources and drains of a metal-oxide semiconductor (MOS) transistors, with dimensions in the range of microns, so as to satisfy the demands of both increasing component density and improving electrical performance. However, the MOS transistors in the periphery circuit region of NROM currently use cobalt (Co), titanium (Ti) or molybdenum (Mo) as metal materials to form the silicide layer, which consume silicon atoms from the source and the drain. Therefore, a deep ion implantation process, having a deep implantation depth, is performed in the formation of the prior art source and drain to compensate for the consumed portions of the source and drain. This is an unfavorable feature of prior art semiconductor processes.

### SUMMARY OF INVENTION

It is therefore a primary objective of the present invention to provide a method of forming a metal-oxide semiconductor (MOS) transistor with a shallow junction in nitride read only memory (NROM).

In a preferred embodiment, the present invention provides a method of forming a metal-oxide semiconductor (MOS) transistor with a shallow junction in nitride read only memory (NROM). The method first provides a semiconductor wafer with both a memory array area and a periphery circuit region defined on the surface of the semiconductor wafer. A gate composed of a silicon oxide layer and a silicon germanium layer is formed on the surface of the periphery circuit region, and a spacer, a source and a drain of the MOS transistor are formed around the gate. Finally, a nickel (Ni) layer is formed on the surface of the source and the drain, and a rapid thermal annealing process (RTA process) with a temperature ranging between 400° C. and 500° C. is performed to form a silicon nickel layer on the surface of the source and the drain. Furthermore, a shallow junction for the source and the drain can be formed.

In contrast to the prior MOS transistor formed in a periphery circuit region, the MOS transistor manufactured by the present invention uses a nickel (Ni) layer as the metal material for forming a silicide layer. The silicon nickel layer formed by reacting the nickel layer with surfaces of the source and drain of the MOS transistor consumes a small amount of silicon atoms in the silicon substrate, so enabling the formation of a shallow junction for the source and the drain.

These and other objectives of the present invention will no doubt become obvious to those of ordinary skill in the art after having read the following detailed description of the preferred embodiment, which is illustrated in the various figures and drawings.

### BRIEF DESCRIPTION OF DRAWINGS

FIG. 1 to FIG. 6 are cross-sectional diagrams of a method of forming an NROM according to the prior art.

FIG. 7 to FIG. 9 are cross-sectional diagrams of a method of forming a MOS transistor with a shallow junction in NROM according to the present invention.

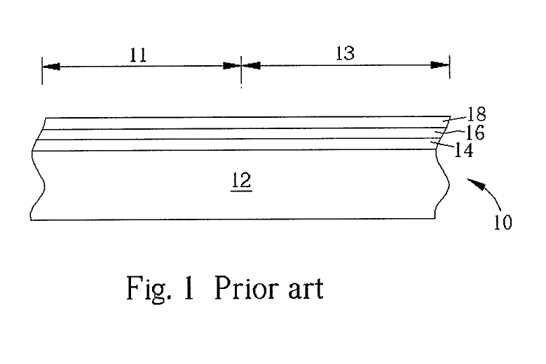

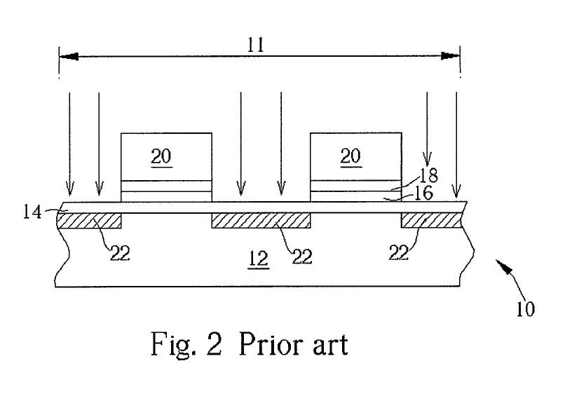

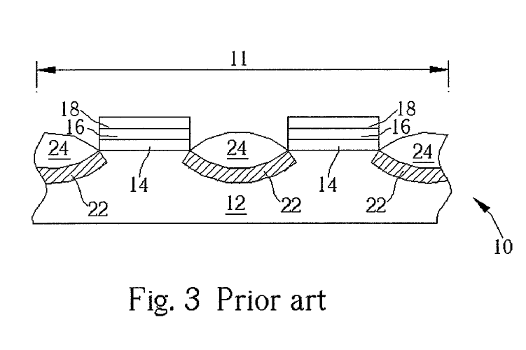

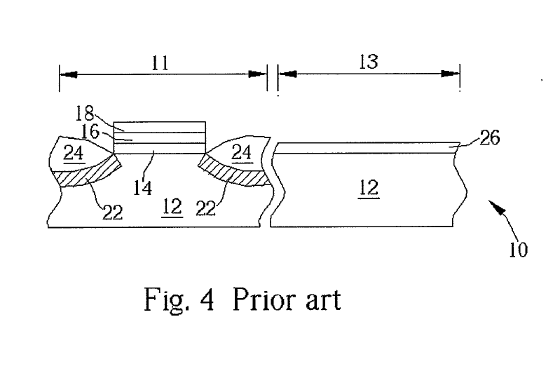

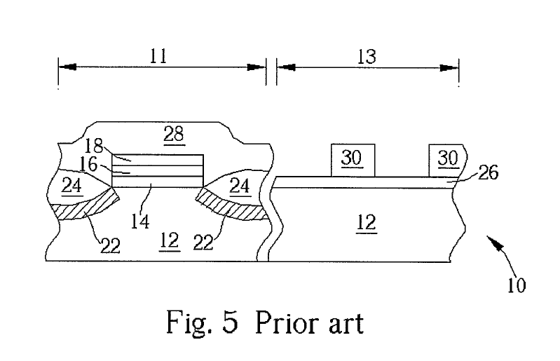

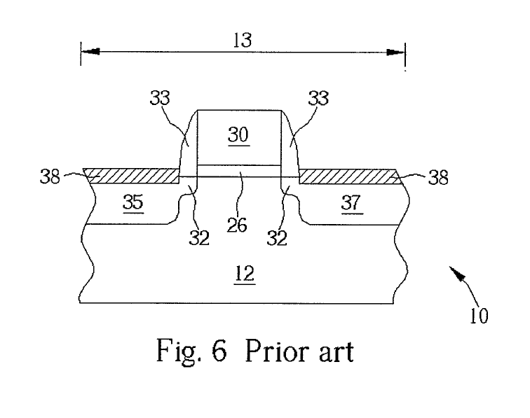

### DETAILED DESCRIPTION

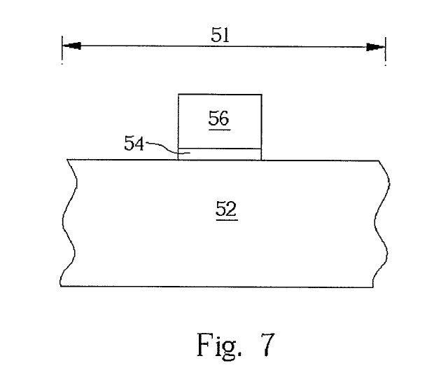

Please refer to FIG. 7 to FIG. 9. FIG. 7 to FIG. 9 are cross-sectional diagrams of a method of forming a MOS transistor with a shallow junction in NROM according to the present invention.

In a preferred embodiment, a semiconductor wafer is first provided with both a memory array area (not shown) and a periphery circuit region 51 defined on the surface of a silicon substrate 52. A plurality of NROM memory cells are formed in the memory array area, and each NROM memory cell comprises a MOS transistor and a silicon nitride layer. However, the MOS transistor with a shallow junction of the present invention is formed in the periphery circuit region 51. The method of manufacturing NROM memory cells in the memory array area requires first forming a patterned ONO dielectric layer on the surface of the silicon substrate 52. Then, a plurality of bit lines and a field oxide layer are formed on the silicon substrate 52. Finally, a threshold voltage level adjustment implantation for the MOS transistors in the periphery circuit region 51 is performed, and the ONO dielectric layer on the surface of the periphery circuit region 51 is removed.

As shown in FIG. 7, a silicon oxide layer is then formed on the surface of the periphery circuit region 51, which functions as a gate oxide layer 54 of a NMOS transistor or a PMOS transistor. Thereafter, a silicon germanium layer with a chemical composition of Si_{1-X}Ge_{X}, where x=0.05˜1.0, is formed on the silicon oxide layer. An etching process is performed to etch the silicon germanium layer and the silicon oxide layer to form a gate 56 of the MOS transistor on the silicon substrate 52. The silicon germanium layer is formed by a chemical vapor deposition (CVD) process aerating silane (SiH₄), germane (GeH₄) and hydrogen at a temperature ranging between 450° C. and 620° C.

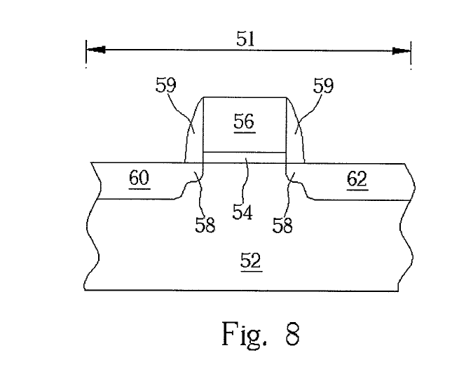

As shown in FIG. 8, a first ion implantation process is performed to form a lightly doped drain (LDD) 58 for the MOS transistor. Then a spacer 59 is formed around the gate 56, and a second ion implantation process is performed to form two doping areas on the silicon substrate 52 on two related sides of the gate 56 (generally, on two opposite sides of the gate 56). Next, a high temperature annealing process is performed to drive the dopants from the second ion implantation process into the two doping areas, forming a source 60 and a drain 62 of the MOS transistor.

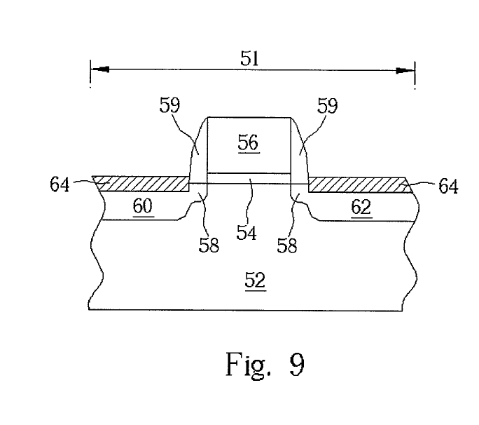

As shown in FIG. 9, a nickel (Ni) layer (not shown) is formed on the surface of the source 60 and the drain 62. A rapid thermal annealing process (RTA process) follows with a temperature between 400° C. and 500° C. to react the nickel layer with the surface of the source 60 and the drain 62 so as to form a silicon nickel layer 64 on the surface of the source 60 and the drain 62. Finally, the portion of the nickel layer that does not participate in the reaction is removed, and the formation of the MOS transistor is complete.

The MOS transistor in an NROM manufactured by the present invention uses a nickel (Ni) layer as the metal material for forming a silicide layer on surfaces of a source and a drain. The silicon nickel layer formed by reacting the nickel layer with surfaces of the source and the drain consumes a small amount of silicon atoms in the silicon substrate. Therefore, in contrast to the MOS transistor of prior art, a shallow junction for the source and the drain of the present invention MOS transistor can be formed to satisfy both the demands of increasing component density and improving electrical performance.

Those skilled in the art will readily observe that numerous modifications and alterations of the device may be made while retaining the teachings of the invention. Accordingly, the above disclosure should be constructed as limited only by the metes and bounds of the appended claims.

What is claimed is:

1. A method of forming a metal-oxide semiconductor (MOS) transistor with a shallow junction in nitride read only memory (NROM), the method comprising:
providing a semiconductor wafer with both a memory array area and a periphery circuit region defined on a surface of a substrate of the semiconductor wafer;
forming a silicon oxide layer on the surface of the periphery circuit region;
forming a silicon germanium layer on the surface of the silicon oxide layer;
patterning the silicon germanium layer to form a gate of the MOS transistor on the surface of the substrate;
forming a spacer around the gate;
forming a source and a drain of the MOS transistor in the substrate;
forming a nickel (Ni) layer on the surface of the source and the drain; and
performing a rapid thermal annealing process (RTA process) to react the nickel layer with the surface of the source and the drain to form a silicon nickel layer.

2. The method of claim 1 wherein the silicon germanium layer comprising a chemical composition of Si_{1-X}Geₓ, with x=0.05 to 1.0.

3. The method of claim 1 wherein patterning the silicon germanium layer further patterning the silicon oxide layer.

4. The method of claim 1 wherein the silicon oxide layer functions as a gate oxide layer of the MOS transistor.

5. The method of claim 1 wherein the MOS transistor is an NMOS transistor or a PMOS transistor.

6. The method of claim 1 further comprising a first ion implantation process for forming a lightly doped drain (LDD) of the MOS transistor.

7. The method of claim 1 wherein forming the source and the drain comprises:
performing a second ion implantation process to form two doping areas on the substrate adjacent to two related sides of the gate; and
performing a thermal annealing process to drive dopants into the two doping areas to form the source and drain.

8. The method of claim 1 wherein the substrate is a silicon substrate.

9. The method of claim 8 wherein the silicon nickel layer formed by reacting the nickel layer with the surface of the source and the drain consumes silicon atoms in the silicon substrate so as to form a shallow junction of the source and the drain.

10. The method of claim 1 wherein the silicon germanium layer is formed by performing a chemical vapor deposition (CVD) process utilizing silane (SiH₄), germane (GeH₄) and hydrogen at a temperature ranging between 450° C. and 620° C.

11. The method of claim 1 wherein a plurality of NROM memory cells are formed in the memory array area, and each NROM memory cell comprises a MOS transistor and a silicon nitride layer.

12. A method of forming a metal-oxide semiconductor (MOS) transistor with a shallow junction, the method comprising:
providing a semiconductor wafer;
forming a silicon oxide layer on a silicon substrate of the semiconductor wafer;
performing an in-situ doped chemical vapor deposition (CVD) process for forming a silicon germanium layer on the surface of the silicon oxide layer;
patterning the silicon germanium layer to form a gate of the MOS transistor on the surface of the silicon substrate;
forming a spacer around the gate;
performing a first ion implantation process to form two doping areas on the silicon substrate adjacent to two related sides of the gate;
performing a thermal annealing process to drive dopants into the two doping areas to form a source and a drain of the MOS transistor;
forming a nickel (Ni) layer on the surface of the source and the drain; and
performing a rapid thermal annealing process (RTA process) to react the nickel layer with the surface of the source and the drain to form a silicon nickel layer on the surface of the source and the drain.

13. The method of claim 12 wherein patterning the silicon germanium layer further pattering the silicon oxide layer.

14. The method of claim 12 wherein the silicon oxide layer functions as a gate oxide layer of the MOS transister.

15. The method of claim 12 wherein the MOS transistor is an NMOS transistor or a PMOS transister.

16. The method of claim 12 further comprising a second ion implantation process for forming a lightly doped drain (LDD) of the MOS transistor.

17. The method of claim 12 wherein process gases of the in-situ doped CVD process comprise silane (SiH₄) germane (GeH₄) and hydrogen, and the process temperature of the in-situ doped CVD process ranges between 450° C. and 620° C.
